(19) United States
(12) Patent Application Publication
(10) Pub. No.: US 2024/0386163 A1
(43) Pub. Date: Nov. 21, 2024

(54) Method for Simulating and Predicting Deep Reservoir Structural Fractures in Consideration of Thickness Change

(71) Applicants: China University of Mining and Technology, Xuzhou City (CN); Shanxi Huayang Group New Energy Co., Ltd., No. 1 Mine, Yangquan City (CN)

(72) Inventors: Zhenghui Qu, Xuzhou City (CN); Bangxu Rong, Xuzhou City (CN); Liang Guo, Yangguan City (CN); Kebin Wei, Xuzhou City (CN); Qingtian Zhang, Xuzhou City (CN); Changxing Li, Xuzhou City (CN); Jie Luo, Xuzhou City (CN); Weike Wan, Xuzhou City (CN); Xingyun Liu, Xuzhou City (CN); Weijun Hou, Xuzhou City (CN)

(73) Assignees: China University of Mining and Technology, Xuzhou City (CN); Shanxi Huayang Group New Energy Co., Ltd., No. 1 Mine, Yangquan City (CN)

(21) Appl. No.: 18/788,118

(22) Filed: Jul. 29, 2024

(51) Int. Cl. G06F 30/20

(52) U.S. Cl. CPC G06F 30/20

(57) ABSTRACT

A method for simulating and predicting deep reservoir structural fractures in consideration of thickness change is disclosed. The method firstly calculates a structural fracture apparent density by using a stress-based reservoir structural fracture prediction formula group, secondly obtains structural fracture linear density based on simulation experiment, thickness unit division and reservoir structural fracture prediction optimization formula, finally carries out a reliability judgment based on the structural fracture linear density, the apparent density and the measured inspection values by using parameter inspection and error analysis. The above method can effectively reduce the difficulty and cost of energy development.

### TECHNICAL FIELD

The present disclosure relates to the field of geological exploration and development of unconventional energy reservoirs, in particular to a method for simulating and predicting deep reservoir structural fractures in consideration of thickness change.

### BACKGROUND

In the process of exploration and development of deep unconventional energy sources (deep geothermal energy, coalbed methane, shale gas and tight sandstone gas, etc.), the development characteristics of reservoir structural fractures are indispensable, they are related to the permeability and reformability of reservoirs, and they are key parameters to determine the sweet spot zone and the reservoir reformation scheme. The formation of structural fractures comes from the fact that the stress in earth crust approaches or exceeds the rock strength limit, which causes the internal bonding force of the rock to be damaged so that the rock loses its integrity. Therefore, predicting the development of reservoir structural fractures from the perspective of stress has become a main method and has been continuously improved.

For the fine prediction of reservoir structural fractures, the conventional technology has the following deficiencies: I. The apparent density value of structural fractures obtained based on the above method is too different from the measured simulation constraint value and simulation inspection value. II. It is impossible to explain the close correlation between the change of reservoir thickness and the distribution of structural fractures, and no attempt has been made to solve the problem I from this perspective. The currently known reservoir structural fracture prediction formula group shows that the structural fracture density is only affected by the basic properties of the reservoir such as stress, elastic modulus and Poisson's ratio, and has nothing to do with the thickness. Reservoirs of the same kind having different thicknesses will have the same structural fracture apparent density under the condition of same stress. This cannot explain the close relationship between structural fracture and rock thickness discovered by geologists at all. III. The reliability of the current method and the reliability of the prediction results cannot be predicted. It is difficult to predict or avoid special lithology area, prediction failure area of the reservoir, and research area with obvious changes in reservoir thickness, and it is difficult to provide the required accurate prediction for the production and development of unconventional energy sources. The above deficiencies are fatal for the prediction of structural fractures in unconventional energy sources that require high precision.

### SUMMARY

In view of the above problems, the present disclosure provides a method for simulating and predicting deep reservoir structural fractures in consideration of thickness change that overcomes the above problems or at least partially solves the above problems.

A method for simulating and predicting deep reservoir structural fractures in consideration of thickness change, comprising:
step 1: introducing a stress-based reservoir structural fracture prediction formula group, obtaining relevant coefficients and parameters through methods such as simulation and actual measurement, and obtaining a structural fracture apparent density;
step 2: introducing a reservoir thickness-based structural fracture prediction optimization formula;
step 3: classifying reservoir thickness units according to thickness changes and lithology differences of reservoirs;
step 4: obtaining a first relevant parameter such as a reservoir thickness through measurement, and substituting the first relevant parameter into the optimization formula;
step 5: obtaining a second relevant parameter based on a simulation experiment and a fitting analysis of a simulation constraint value, and substituting the second relevant parameter into the optimization formula;
step 6: substituting the structural fracture apparent density into the optimization formula in which parameters have been determined, to calculate a reservoir structural fracture linear density;
step 7: obtaining a first quantitative opinion based on a significance level, a structural fracture verification value, a parameter inspection and an acceptance domain analysis of a reservoir structural fracture probability density function;
step 8: obtaining a second quantitative opinion by analyzing based on a structural fracture density verification value, and an absolute and a relative error of a structural fracture density;
step 9: considering the first quantitative opinion and the second quantitative opinion to obtain a reliability result for reference analysis.

According to some embodiments of the present disclosure, the step 1 includes the following steps:

Step 1.1: find out the stress-based reservoir structural fracture prediction formula group, the formula group is based on the law of energy conservation and the Coulomb-Moore strength theory, combined with the derivation expansion theory, the relationship between confining pressure and rock fractures, and the maximum strain energy density theory of brittle fracture mechanics, and obtained with the help of volume and linear density transformation models. Specifically, the formula group is:

$$\{ \begin{matrix}{w}_{f} = \frac{1}{2 E} ( {σ}_{1}^{2} + {σ}_{3}^{2} - 2 {μσ}_{1} {σ}_{3} - {0.85}^{2} {σ}_{p}^{2} + 2 {μσ}_{3} 0.85 {σ}_{p} ) \\ {σ}_{p} = \frac{2 {C}_{0} cos φ + ( 1 + sin φ ) {σ}_{3}}{1 - sin φ} \\ {w}_{f} = {D}_{vf} ( {J}_{0} + {σ}_{3} b ) \\ {D}_{lf}^{′} = \frac{2 {D}_{vf} {L}_{1} {L}_{3} sin θ cos θ - {L}_{1} sin θ - {L}_{3} cos θ}{{L}_{1}^{2} {sin}^{2} θ + {L}_{3}^{2} {cos}^{2} θ}\end{matrix}$$

w_{f} is the energy consumption of structural fractures; E is the elastic modulus; μ is Poisson's ratio; σ₁ is the maximum principal stress, σ₃ is the minimum principal stress; C₀ is the cohesion force; J₀ is the fracture surface energy under zero confining pressure; σₚ is the rock fracture stress; φ is the internal friction angle; b is the fracture opening; L₁ is the maximum principal stress surface length; L₃ is the minimum principal stress surface length; θ is the shear angle; D_{vf} is a structural fracture volume density in a unit body—a ratio of a total surface area of a structural fracture body to the volume of the unit body; D′_{lf} is the structural fracture apparent density.

Step 1.2: relevant coefficients are obtained based on query, test and simulation methods. It includes, but not limited to, the relevant coefficients obtained from books and internet inquiries, experimental measurements, etc., for example, elastic modulus E, Poisson's ratio μ, cohesion force C₀, fracture surface energy under zero confining pressure J₀;

Step 1.3: the stress direction of the critical structural period in the region is obtained based on the background analysis of the regional tectonic structural stress, including but not limited to the map analysis of relevant books and articles.

In addition, a physical simulation or software simulation is carried out based on a stress direction, a simulation constraint value and a similar principle, the simulation is carried out by controlling a structural morphology and scale, fault throw, fold curvature and structural fracture density, etc., to achieve a preset state, and finally determine a stress magnitude.

A sample experiment and a simulation experiment are carried out based on a stress state, to measure and obtain the parameters of the formula group—rock fracture stress σₚ, internal friction angle φ, fracture opening b, maximum principal stress surface length L₁, minimum principal stress surface length L₃, and shear angle θ. Parameter acquisition methods include but are not limited to sample measurement, sample experiment, physical and software simulation.

Step 1.4: based on the formula group in step 1.1, the relevant coefficients and parameters in steps 1.2 and 1.3, the reservoir structural fracture apparent density is calculated.

In addition, it should also be known that w_{f} represents the energy consumption of structural fractures; D_{vf} represents a structural fracture volume density in a unit body; D′_{lf} represents the structural fracture apparent density; the maximum principal stress surface and the minimum principal stress surface width L₂.

Furthermore, in step 2, since the distribution of non-homogeneous region of the reservoir is random, it has little effect on the prediction of structural fractures in the region, so the macroscopic research model is considered to be relatively homogeneous in simplification. According to the above, data analysis, fitting analysis and numerical simulation show that for a rock stratum with a thickness of h, structural fractures will be successfully observed in the field when l₂≥h in the σ₂ direction; when l₂<h, the structural fractures in the rock stratum can only be observed with a probability, the fitting takes the mean value. It is also found that the thinner the homogeneous reservoir under the same stress, the greater the density of structural fractures. Reservoir thickness is closely related to fracture density. Based on the analysis of the above problems, the structural fracture prediction optimization formula considering thickness is obtained:

$${D}_{lf} = {D}_{lf}^{′} \times {\int }_{h}^{+ ∞} \frac{1}{\sqrt{2 π} α} {e}^{- \frac{{( {l}_{2} - {l}_{0} )}^{2}}{2 {α}^{2}}} {dl}_{2}$$

Where h is the actual thickness of the reservoir; l₂ is the extension length of the actual reservoir structural fracture in the σ₂ direction under a specific stress; l₀ is the extension length of the ideal homogeneous reservoir structural fracture in the σ₂ direction under a specific stress;

Further, the step 3 is based on a geophysical method, including but not limited to drilling, logging, well-connected section and seism etc., to find out the thickness changes and lithological abnormal area of reservoirs in an area, and divide into thickness unit bodies, which corresponds to finite element divisions in a simulation stage.

Further, said step 4 includes the following steps:

Step 4.1: a reservoir thickness h and a structural fracture extension length l₂ in a σ₂ direction of the reservoir are measured based on the thickness unit bodies and measurement, including but not limited to, obtaining the first relevant parameter based on cores, field outcrops or downhole measurements, earthquakes, etc.—h and l₂;

Step 4.2: substitute the parameters in step 4.1 into the optimization formula to be used in step 2, and improve the first relevant parameter.

Further, said step 5 includes the following steps:

Step 5.1: the simulation experiment and a numerical fitting method of the simulation constraint value is based to obtain a structural fracture extension length l₀ in a σ₂ direction of an ideal homogeneous reservoir and a reservoir homogeneity degree α, the specific method comprises but not limited to software simulation, physical simulation, numerical fitting and moment estimation method, a mean value of parameters is calculated based on a moment estimation method equation set of obtained data, that is, the second relevant parameter l₀ and α.

Step 5.2: the parameters obtained in step 5.1 are substituted into the optimization formula in step 2, and the second relevant parameter in the optimization formula are improved.

Further, in step 6, the structural fracture linear density is calculated by substituting the structural fracture apparent density in step 1.4 into the optimization formula of relevant parameters in steps 4 and 5.

Further, in the step 7, based on the structural fracture linear density measured in exploration and development, the extension length l₀ of ideal structural fracture, the reservoir homogeneity degree α and the significance level, by the hypothesis test of the optimized probability density function of reservoir structural fractures, test l₀ and α respectively, and determine the acceptance domain, and obtain the first quantitative opinion.

The probability density function of the linear density of structural fractures in the reservoir thickness is:

$$f ( {l}_{2} ) = \frac{1}{\sqrt{2 π} α} {e}^{- \frac{{( {l}_{2} - {l}_{0} )}^{2}}{2 {α}^{2}}} {dl}_{2}$$

The hypothesis testing analysis of parameters l₀ and α is specifically: a unknown, test for l₀: significance level β, statistical magnitude rejection domain:

$$\vert t \vert = \frac{\vert {\overline{l}}_{2} - {l}_{0} \vert}{s / \sqrt{n}} \geq {t}_{β / 2} ( n - 1 )$$

l₀ unknown, test for α: significance level β, statistical magnitude rejection domain:

$$\frac{( n - 1 ) {s}^{2}}{{α}^{2}} \geq {χ}_{1 - β / 2}^{2} ( n - 1 ) or \frac{( n - 1 ) {s}^{2}}{{α}^{2}} \geq {χ}_{β / 2}^{2} ( n - 1 )$$

If both the hypothesis tests are met, find the acceptance region of l₂.

Further, in the step 8, the linear density of reservoir structural fractures in the region is calculated by the optimization formula and the absolute and relative error analysis with the linear density of fractures measured in the field is made to judge the reliability and obtain the second quantitative opinion.

$$R = \frac{\begin{matrix}\vert measured structural fracture density - \\ predicted structural fracture density \vert\end{matrix}}{measured structural fracture density} \times 100 \% \\ r = \vert measured structural fracture density - predicted structural fracture density \vert$$

Relative error coefficient R; absolute error coefficient r.

Further, in step 9, based on the parameter inspection analysis and method accuracy verification and conclusion of steps 7 and 8, the reliability results are obtained, which provides reference analysis steps and standards for exploration and development personnel using this method.

Compared with the prior art, the technical solution of the present disclosure has the following advantages:

I. The present disclosure proposes a method for simulating and predicting deep reservoir structural fractures in consideration of thickness change, which is comprehensive in consideration, easy to operate and implement, and aims to reduce the difficulty and cost of unconventional energy exploration and development.

II. This method is an optimization formula for prediction of deep structural fractures based on reservoir thickness, it specifically analyzes the precise relationship between structural fracture apparent density and reservoir thickness, and solves the customization problem of predicting structural fractures based on stress.

III. The present disclosure provides a standard method for predicting structural fractures in deep reservoirs, which can accurately guide the prediction of structural fractures required for exploration and development, and can provide reliability analysis, test predictions and prevent reservoir abnormal areas.

IV. Compared with the stress-based structural fracture prediction method, the structural fracture prediction optimization method in the present disclosure has higher accuracy (relative error<12%, absolute error<7 pieces/m), this accuracy is applicable to all kinds of reservoirs, and can also be competent for the prediction of structural fractures in multiple rock stratums under the same tectonic stress field.

### BRIEF DESCRIPTION OF THE DRAWINGS

FIG. 1 is an application flow chart of a method for simulating and predicting deep reservoir structural fractures in consideration of thickness change according to the present disclosure.

FIG. 2 is a graph showing the relationship between structural fracture parameters and stress.

FIG. 3 is a schematic diagram of the optimization formula for prediction of deep structural fractures considering the thickness.

FIG. 4 is a contour map of the thickness of a coal reservoir in the old factory area 9#used in the example.

FIG. 5 is a contour map of the structural fracture apparent density of a coal reservoir in the old factory area 9#used in the example.

FIG. 6 is a contour map of the structural fracture line density of a coal reservoir in the old factory area 9#used in the example.

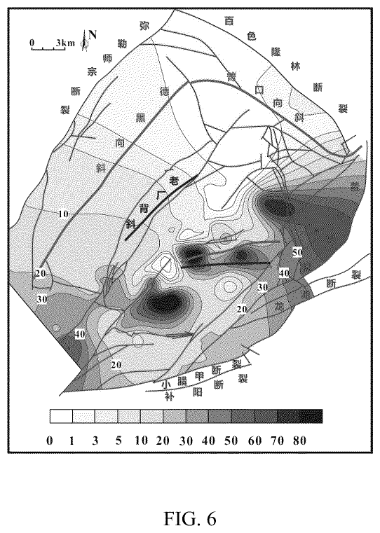

### DETAILED DESCRIPTION OF EMBODIMENTS

The technical solution of the present disclosure will be further described in detail below in conjunction with the accompanying drawings.

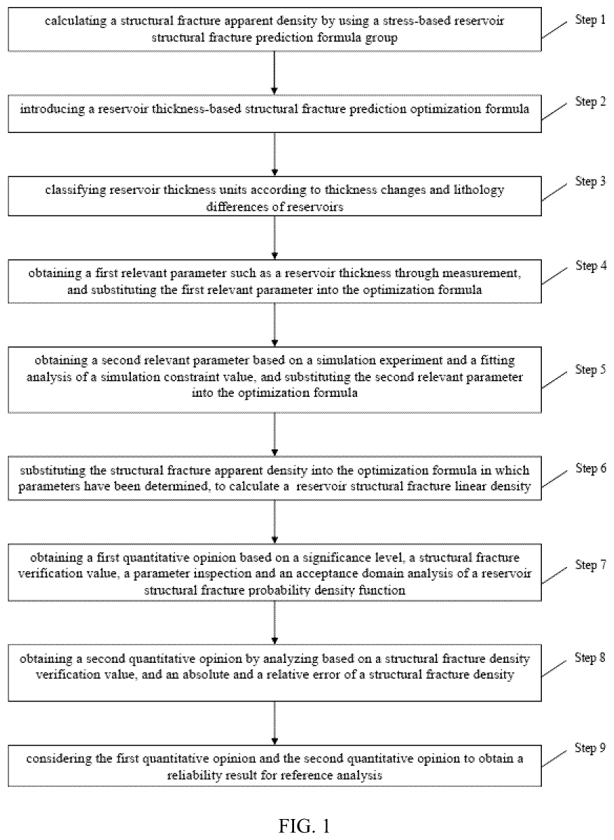

FIG. 1 shows the application process of the structural fracture prediction method, which includes:

Step 1: introducing a stress-based reservoir structural fracture prediction formula group, obtaining relevant coefficients and parameters through methods such as simulation and actual measurement, and obtaining a structural fracture apparent density.

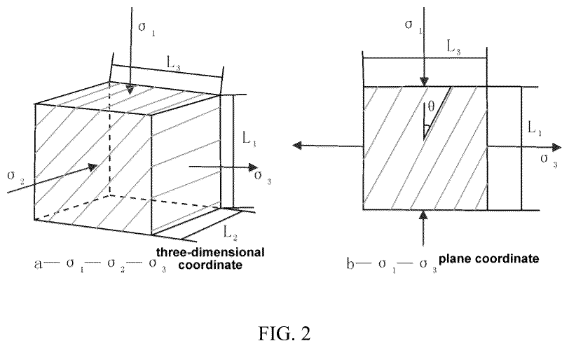

Herein, the linear density of fractures is studied based on the stress-based reservoir structural fracture prediction formula group, it acts with conjugate shear fracture as the research target, it is based on the law of energy conservation and the Coulomb-Moore strength theory, combined with the derivation expansion theory, the relationship between confining pressure and rock fractures, and the maximum strain energy density theory of brittle fracture mechanics, and obtained with the help of the compression test results of Xia Jixiang, Wang Bifeng, etc. and the volume and linear density transformation models shown in FIG. 2. Specifically, this formula group is:

$$\{ \begin{matrix}{w}_{f} = \frac{1}{2 E} ( {σ}_{1}^{2} + {σ}_{3}^{2} - 2 {μσ}_{1} {σ}_{3} - {0.85}^{2} {σ}_{p}^{2} + 2 {μσ}_{3} 0.85 {σ}_{p} ) \\ {σ}_{p} = \frac{2 {C}_{0} cos φ + ( 1 + sin φ ) {σ}_{3}}{1 - sin φ} \\ {w}_{f} = {D}_{vf} ( {J}_{0} + {σ}_{3} b ) \\ {D}_{lf}^{′} = \frac{2 {D}_{vf} {L}_{1} {L}_{3} sin θ cos θ - {L}_{1} sin θ - {L}_{3} cos θ}{{L}_{1}^{2} {sin}^{2} θ + {L}_{3}^{2} {cos}^{2} θ}\end{matrix}$$

Relevant coefficients are obtained based on query, test and simulation methods, it includes, but not limited to, the relevant coefficients obtained from books and internet inquiries, experimental measurements, etc., for example, elastic modulus E, Poisson's ratio μ, cohesion force C₀ (which means the shear strength when C₀=0), and the fracture surface energy J₀ under zero confining pressure (equivalent to the fracture surface energy obtained from the uniaxial compression experiment). The stress direction of the critical structural period in the region is obtained based on the background analysis of the regional tectonic structural stress, including but not limited to the map analysis of relevant books and articles. In addition, a simulation experiment (including but not limited to physical sandbox simulation and software simulation methods, etc.) is carried out based on a stress direction, a simulation constraint value and a similar principle, the simulation is carried out by controlling a structural morphology and scale, fault throw, fold curvature and structural fracture density, etc., to achieve a preset state, and finally determine a stress magnitude—the maximum principal stress σ₁, the minimum principal stress σ₃. A sample experiment and a simulation experiment are carried out based on a stress state, to measure and obtain the parameters of the formula group—rock fracture stress σₚ, internal friction angle o, fracture opening b, maximum principal stress surface length L₁, minimum principal stress surface length L₃, and shear angle θ. Parameter acquisition methods include but are not limited to sample measurement, sample experiment, physical and software simulation. The relevant coefficients and parameters are substituted into the formula group finally determined based on the volume and linear density conversion model in FIG. 2 to calculate the reservoir structural fracture apparent density D′_{lf}.

Step 2: introducing a reservoir thickness-based structural fracture prediction optimization formula.

Herein, according to the principle of macroscopic homogeneity, the distribution of non-homogeneous region of the reservoir is random, it has little effect on the prediction of structural fractures in the region, so the macroscopic research model is considered to be relatively homogeneous in simplification, and it has little macroscopic impact on the prediction of reservoir structural fractures. According to the above, data analysis, fitting analysis and numerical simulation show that for a rock stratum with a thickness of h, structural fractures will be successfully observed in the field when l₂≥h in the σ₂ direction; when l₂<h, the structural fractures in the rock stratum can only be observed with a probability, the fitting takes the mean value. Based on the analysis of the above problems, the structural fracture prediction optimization formula considering thickness is obtained:

$${D}_{lf} = {D}_{lf}^{′} \times {\int }_{h}^{+ ∞} \frac{1}{\sqrt{2 π} α} {e}^{- \frac{{( {l}_{2} - {l}_{0} )}^{2}}{2 {α}^{2}}} {dl}_{2}$$

Step 3: classifying reservoir thickness units according to thickness changes and lithology differences of reservoirs;

Herein, the geophysical methods include but not limited to drilling, well logging, well-connected section and seism etc., to find out the thickness changes and lithological abnormal area of reservoirs in an area, and divide into thickness units according to the principle of equal thickness and avoiding obtuse angle, which corresponds to finite element divisions in a simulation stage

Step 4: obtaining a first relevant parameter such as a reservoir thickness through measurement, and substituting the first relevant parameter into the optimization formula.

Based on thickness unit bodies and measurement, including but not limited to, cores, field outcrops or downhole measurements, earthquakes, etc., the first relevant parameter (a reservoir thickness h and a structural fracture extension length l₂ in a σ₂ direction of the reservoir) are measured, and they are substituted into structural fracture prediction optimize formula.

Step 5: obtaining a second relevant parameter based on a simulation experiment and a fitting analysis of a simulation constraint value, and substituting the second relevant parameter into the optimization formula.

Herein, the experimental analysis methods include but not limited to software simulation, physical simulation, numerical fitting and moment estimation method. Based on the moment estimation method equation set of the obtained data, the mean value of the parameters is calculated—a structural fracture extension length lo in a σ₂ direction of an ideal homogeneous reservoir and a reservoir homogeneity degree a (that is, the standard deviation of the extension length of the ideal reservoir structural fracture in the σ₂ direction) are substituted into the optimization formula.

Step 6: substituting the structural fracture apparent density into the optimization formula in which parameters have been determined, to calculate a reservoir structural fracture linear density.

Herein, the structural fracture linear density is calculated by substituting the structural fracture apparent density obtained in step 1.4 into the optimization formula of relevant parameters in steps 4 and 5.

Step 7: obtaining a first quantitative opinion based on a significance level, a structural fracture verification value, a parameter inspection and an acceptance domain analysis of a reservoir structural fracture probability density function.

Based on the structural fracture linear density measured in exploration and development, the extension length l₀ of ideal structural fracture, the reservoir homogeneity degree α and the significance level, by the hypothesis test of the optimized probability density function of reservoir structural fractures, test l₀ and α respectively, and determine the acceptance domain, and obtain the first quantitative opinion.

The probability density function of the linear density of structural fractures in the reservoir thickness is:

$$f ( {l}_{2} ) = \frac{1}{\sqrt{2 π} α} {e}^{- \frac{{( {l}_{2} - {l}_{0} )}^{2}}{2 {α}^{2}}} {dl}_{2}$$

The hypothesis testing analysis of parameters l₀ and α is specifically:
α unknown, test for l₀: significance level β, according to the sample size n, sample mean l₀ and sample standard deviation s in the simulated test value, the statistical magnitude rejection domain is determined:

$$\vert t \vert = \frac{\vert {\overline{l}}_{2} - {l}_{0} \vert}{s / \sqrt{n}} \geq {t}_{β / 2} ( n - 1 )$$

And check whether l₀ is reasonable;
l₀ unknown, test for α: significance level β, according to the sample size n and sample variance s², the statistical magnitude rejection domain is determined:

$$\frac{( n - 1 ) {s}^{2}}{{α}^{2}} \geq {χ}_{1 - β / 2}^{2} ( n - 1 ) or \frac{( n - 1 ) {s}^{2}}{{α}^{2}} \geq {χ}_{β / 2}^{2} ( n - 1 )$$

And check whether α is reasonable;

If both hypothesis tests are met, find the acceptance region of l₂. For the situation where the hypothesis test is not met, the non-homogeneous region in the macro-homogeneous reservoir in the area can be determined, geological research is carried out in detail, the “sweet spot zone” and “avoidance zone” are analyzed, and similar regions are evaluated by seismic analysis.

Step 8: obtaining a second quantitative opinion by analyzing based on a structural fracture density verification value, and an absolute and a relative error of a structural fracture density.

Herein, the linear density of reservoir structural fractures in the region is calculated by the optimization formula and the absolute and relative error analysis with the linear density of fractures measured in the field is made to judge the reliability and obtain the second quantitative opinion.

$$R = \frac{\begin{matrix}\vert measured structural fracture density - \\ predicted structural fracture density \vert\end{matrix}}{measured structural fracture density} \times 100 \% \\ r = \vert measured structural fracture density - predicted structural fracture density \vert$$

Step 9: considering the first quantitative opinion and the second quantitative opinion to obtain a reliability result for reference analysis.

Herein, it is found through the experiment that the homogeneity degree of the reservoir formed by the provenance of the same stress and the same period is basically a fixed value, with a very few numerical value floating up and down. However, in the non-homogeneous region of the macroscopically homogeneous reservoir, the fail prediction may happen, and the test disagrees and the error is too large. For the reliability analysis based on this, the anomaly area in the whole region can be queried by comparing the seismic profile.

### Explanation of Original Drawings

As shown in FIG. 2, it is a volume and line density transformation model.

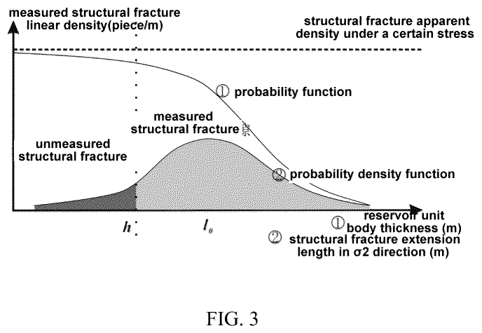

As shown in FIG. 3, the line \textcircled{1} is a probability function, which refers to the linear density of structural fractures corresponding to the thickness h of the unit body (h≥l₂) under a certain stress, the upper limit is the structural fracture apparent density under the stress condition. The line \textcircled{2} represents a probability density function, which refers to the probability density of the structural fracture extension length l₂ of a unit body under a certain stress.

### APPLICATION EXAMPLES

In the simulation prediction of coal reservoir structural fractures in the old factory area in the eastern region of Yunnan province, through the actual measurement of simulation constraint values, software equivalent simulation experiments, stress-based structural fracture prediction formula group and reservoir structural fracture prediction optimization formulas considering thickness changes, the mutual verification and reliability analysis of the result values proved the reliability of the method.

First, the reservoir structural fracture apparent density is calculated based on the formula group in step 1 and the relevant coefficients and parameters determined by the properties of the rock stratum itself and the stress field. The calculation of the relevant coefficients and parameters in this example selects the widely developed siltstone layer and the 9#coal reservoir in Longtan Formation (P₃l) in the old factory area as the research object, and its structural development is dominated by the Indosinian tectonic stress field, specifically Table 1 is obtained by the step 1.2, the step 1.3 calculates the maximum principal stress and minimum principal stress in Table 2based on the simulation constraint values, and the steps 1.1, 1.2, 1.3 and 1.4 calculate the volume density of reservoir structural fractures and apparent density of reservoir structural fractures in Table 2.

TABLE 1
Relevant coefficients and parameters in the old factory area

| | | | | | Internal | Bursting | Breaking |
|---|---|---|---|---|---|---|---|
| | | | Thickness | Cohesion | friction | stress | angle |
| Lithology | No. | Type | (m) | force (Pa) | angle (°) | (Pa) | (°) |
| Siltstone | 92312 | Simulation | 0.09 | 2*10⁶ | 35 | 55604506.41 | 27.5 |
| | | constraint value | | | | | |
| | 92316 | Simulation | 0.1 | 2*10⁶ | 35 | 55559855.33 | 27.5 |
| | | constraint value | | | | | |
| | 92404 | Simulation | 0.12 | 2*10⁶ | 35 | 53060870.62 | 27.5 |
| | | constraint value | | | | | |
| Coal | 92505 | Simulation | 1.7 | 0.6*10⁶ | 27 | 37497552.02 | 31.5 |
| reservoir | | inspection value | | | | | |
| | 92604 | Simulation | 1.2 | 0.6*10⁶ | 27 | 33356147.84 | 31.5 |
| | | inspection value | | | | | |

| | | | | | fracture | | |
|---|---|---|---|---|---|---|---|
| | | | Elastic | | surface | | |
| | | Poisson's | modulus | fracture | energy | L₁ | L₃ |
| Lithology | No | ratio | (Pa) | opening (m) | (J/m²) | (m) | (m) |
| Siltstone | 92312 | 0.24 | 3.9*10⁹ | 0.0014 | 1000 | 1 | 1 |
| | 92316 | 0.24 | 3.9*10⁹ | 0.0014 | 1000 | 1 | 1 |
| | 92404 | 0.24 | 3.9*10⁹ | 0.0014 | 1000 | 1 | 1 |
| Coal | 92505 | 0.3 | 2*10⁹ | 0.000375 | 600 | 1 | 1 |
| reservoir | 92604 | 0.3 | 2*10⁹ | 0.000375 | 600 | 1 | 1 |

TABLE 2
Simulated finite element stress test, calculation results of apparent density of structural
fractures and measured linear density of structural fractures in the old factory area

| | | | | | | measured |
|---|---|---|---|---|---|---|
| | | | Minimum | | apparent density | linear density |
| | | Maximum | principal | Volume density of | of structural | of structural |
| | | principal | stress | structural fractures | fractures | fractures |
| Lithology | No. | stress(Pa) | (Pa) | (number/m³) | (number/m) | (number/m) |
| Siltstone | 92312 | 96111300.00 | 12986000.00 | 45.90469063 | 36.25416173 | 19 |
| | 92316 | 96050500.00 | 12973900.00 | 45.89184645 | 36.24364039 | 19 |
| | 92404 | 96083800.00 | 12296700.00 | 49.6074251 | 39.28726424 | 18 |
| Coal | 92505 | 96716500.00 | 13345900.00 | 356.7120469 | 316.4576223 | 30 |
| reservoir | 92604 | 96267900.00 | 11790700.00 | 404.3697818 | 358.9209751 | 78 |

Secondly, the numerical fitting based on the simulation constraint value (FIG. 3) introduces the reservoir structural fracture optimization formula considering the thickness change, and substitutes the corresponding thickness h based on the thickness unit body (corresponding to the finite element subdivision), the extension length l₀ of the ideal homogeneous reservoir structural fracture in the σ₂ direction obtained based on the simulation constraint value, and the standard deviation α of the extension length of the ideal reservoir structural fracture in the σ₂ direction into the formula (steps 4 and 5), and the normal probability of different thickness unit bodies of siltstone and coal reservoir in the old factory area is calculated (see Table 3). Finally, based on the apparent density of structural fractures obtained in step 1, the results in Table 3 and the step 6, the linear density of structural fractures is calculated (see Table 4).

$$P = {\int }_{h}^{+ ∞} \frac{1}{\sqrt{2 π} α} {e}^{- \frac{{( {l}_{2} - {l}_{0} )}^{2}}{2 {α}^{2}}} {dl}_{2}$$

TABLE 3
Ideal reservoir extension length l₀ of simulation constraint value,
standard deviation α and normal probability calculation result

| | | | Thick- | | | normal |
|---|---|---|---|---|---|---|
| Lithology | No. | Type | ness | l₀ | α | probability |
| Siltstone | 92312 | Simulation | 0.09 | 0 | 2 | 0.482053654 |
| | 92316 | constraint | 0.1 | 0 | 2 | 0.480061194 |
| | 92404 | value | 0.12 | 0 | 2 | 0.476077817 |
| | | Simulation | | | | |
| | | constraint | | | | |
| | | value | | | | |
| | | Simulation | | | | |
| | | constraint | | | | |
| | | value | | | | |
| Coal | 92505 | Simulation | 1.7 | 0 | 1.36 | 0.105649774 |
| reservoir | | inspection | | | | |
| | | value | | | | |
| | 92604 | Simulation | 1.2 | 0 | 1.36 | 0.188792988 |
| | | inspection | | | | |
| | | value | | | | |

TABLE 4
Calculation results of linear densities of structural fractures
in different thickness unit bodies in the old factory area

| | | | | | Calculated |
|---|---|---|---|---|---|
| | | | apparent | | linear |
| | | | density of | | density of |
| | | Thick- | structural | | structural |
| | | ness | fractures | normal | fractures |
| Lithology | No. | (m) | (number/m) | probability | (number/m) |
| Siltstone | 92312 | 0.09 | 36.25416173 | 0.482053654 | 17.48 |
| | 92316 | 0.1 | 36.24364039 | 0.480061194 | 17.40 |
| | 92404 | 0.12 | 39.28726424 | 0.476077817 | 18.70 |
| Coal | 92505 | 1.7 | 316.4576223 | 0.105649774 | 33.43 |
| reservoir | 92604 | 1.2 | 358.9209751 | 0.188792988 | 67.76 |

Thirdly, use the simulation test value of structural fracture density and the probability density function and probability calculation result (simulation prediction value) based on the simulation prediction value, carry out the parameter test analysis in step 7, and obtain the acceptance region, carry out a set of reliability analysis for error analysis, the same as that in step 8, and finally obtain the following results (Table 5). In addition, an error analysis based on the simulated test value and the apparent density of structural fractures is also carried out, and the following results are obtained in Table 6 to evaluate the accuracy of the methods.

TABLE 5
Reliability analysis of structural fracture development based on coal reservoir simulation
test value and prediction value in the old factory area (significance level β = 0.05)

| | | Measured linear | | | | |
|---|---|---|---|---|---|---|
| | | density of structural | Calculated linear | | | Unit body l₂ |
| | | Measured linear | density of structural | Relative | Absolute | acceptance |
| Lithology | No. | fractures(number/m) | fractures(number/m) | error(%) | error(number/m) | domain(m) |
| Coal reservoir | 92505 | 30 | 33.43 | 11.45% | 3.43 | (0.54, 1.414) |
| of Bailongshan | | | | | | |
| Mine | | | | | | |
| Coal reservoir | 92604 | 78 | 67.76 | 13.13% | 10.24 | (0.6, 1.414) |
| of Xiongtong | | | | | | |
| Coal Mine | | | | | | |

Note:
The measured points-the data of coal reservoir 92505 and 92604 are simulation inspection values, and the calculated linear density of structural fractures is simulation prediction value.

TABLE 6
Error analysis of structural fracture development
based on coal reservoir simulation test value and structural
fracture apparent density in the old factory area

| | | Measured | Calculated | | |
|---|---|---|---|---|---|
| | | linear | apparent | | |
| | | density of | density of | | |
| | | structural | structural | Relative | Absolute |
| | | fractures | fractures | error | error |
| Lithology | No. | (number/m) | (number/m) | (%) | (number/m) |
| Coal reservoir | 92505 | 30 | 316.46 | 954.87% | 286.46 |
| of Bailongshan | | | | | |
| Mine | | | | | |
| Coal reservoir | 92604 | 78 | 358.92 | 360.15% | 280.92 |
| of Xiongtong | | | | | |
| Coal Mine | | | | | |

Note:
The result is not credible if the error is too large. The reliability analysis has carried out the error analysis but not the parameter test analysis to obtain the acceptance domain.

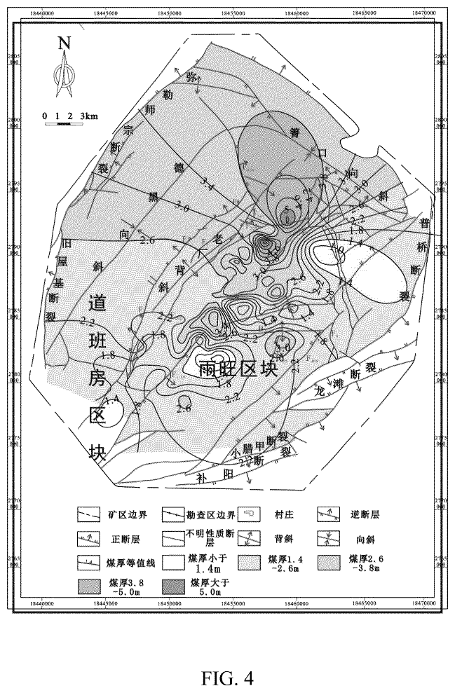

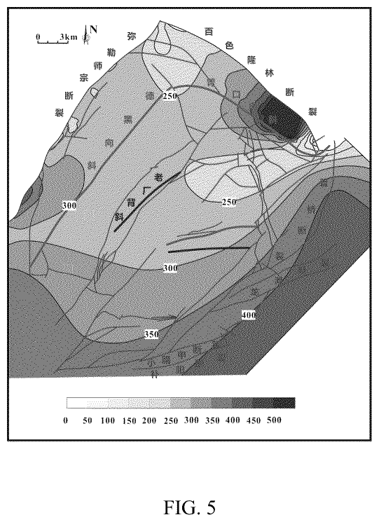

Finally, the application of the results analysis based on Table 5 and Table 6, and the comparative analysis of contour map of the apparent density of structural fractures and the linear density of structural fractures (FIG. 4 and FIG. 5), it shows the application of the contour map of the linear density of structural fractures completely complies with the geological laws and actual structural fracture density distribution law—the relative error of relatively hard rocks with less developed fractures is not more than 10%, and the absolute error is less than 2 pieces/m; the relative error of the relatively fragile coal with more developed fractures is not more than 15%, and the absolute error is less than 10 pieces/m, and the l₂ acceptance domain at the significance level β=0.05 conforms to the actual range and regional law (showing the acquisition accuracy of l₀ and α and the precision of the method). Compared with the stress-based structural fracture prediction method, there is no large difference between the apparent density of structural fractures and the simulation constraint value. The simulation prediction method of reservoir structural fractures that considers thickness changes can more efficiently serve the prediction of the production of coal bed gas in the old factory area in the eastern region of Yunnan province, and from the non-identical lithology and mapping accuracy of the simulation constraint value and simulation inspection value, it can be seen that this method is suitable for the prediction of the development of structural fractures in various rock types of reservoirs and multi-rock types across reservoir rocks (step 9).

The above is only the optional embodiment of the present disclosure, and the scope of protection of the present disclosure is not limited to the above-mentioned embodiment. Equivalent modifications or changes made by those skilled in the field of exploration and development of unconventional energy (deep geothermal, coalbed methane, shale gas and tight sandstone gas, etc.) and material research, based on the present disclosure shall be included in the scope of protection described in the claims.

What is claimed is:

1. A method for simulating and predicting deep reservoir structural fractures in consideration of thickness change, comprising:
step 1: calculating a structural fracture apparent density by using a stress-based reservoir structural fracture prediction formula group;
step 2: introducing a reservoir thickness-based structural fracture prediction optimization formula, which is:
$${D}_{lf} = {D}_{lf}^{′} \times {\int }_{h}^{+ ∞} \frac{1}{\sqrt{2 π} α} {e}^{- \frac{{( {l}_{2} - {l}_{0} )}^{2}}{2 {α}^{2}}} {dl}_{2}$$
step 3: classifying reservoir thickness units according to thickness changes and lithology differences of reservoirs;
step 4: obtaining a first relevant parameter such as a reservoir thickness through measurement, and substituting the first relevant parameter into the optimization formula;
step 5: obtaining a second relevant parameter based on a simulation experiment and a fitting analysis of a simulation constraint value, and substituting the second relevant parameter into the optimization formula;
step 6: substituting the structural fracture apparent density into the optimization formula in which parameters have been determined, to calculate a reservoir structural fracture linear density;
step 7: obtaining a first quantitative opinion based on a significance level, a structural fracture verification value, a parameter inspection and an acceptance domain analysis of a reservoir structural fracture probability density function;
step 8: obtaining a second quantitative opinion by analyzing based on a structural fracture density verification value, and an absolute and a relative error of a structural fracture density;
step 9: considering the first quantitative opinion and the second quantitative opinion to obtain a reliability result for reference analysis.

2. The method for simulating and predicting deep reservoir structural fractures in consideration of thickness change according to claim 1, wherein
in the step 1, a physical simulation or software simulation is carried out based on a stress direction, a simulation constraint value (measured fracture data used for modeling) and a similar principle, the simulation is carried out by controlling a structural morphology and scale, fault throw, fold curvature and structural fracture density, etc., to achieve a preset state, and finally determine a stress magnitude; a sample experiment and a simulation experiment of field outcrop and drilling core sampling are carried out based on a stress state, and a reservoir fracture density is obtained.

3. The method for simulating and predicting deep reservoir structural fractures in consideration of thickness change according to claim 1, wherein
the step 3 is based on a geophysical method, including but not limited to drilling, logging, well-connected section and seism etc., to find out the thickness changes and lithological abnormal area of reservoirs in an area, and divide into thickness unit bodies, which corresponds to finite element divisions in a simulation stage.

4. The method for simulating and predicting deep reservoir structural fractures in consideration of thickness change according to claim 1, wherein
in the step 4, a reservoir thickness h and a structural fracture extension length l₂ in a σ₂ direction of the reservoir are measured based on the thickness unit bodies and measurement.

5. The method for simulating and predicting deep reservoir structural fractures in consideration of thickness change according to claim 1, wherein
in the step 5, the simulation experiment and a numerical fitting method of the simulation constraint value is based to obtain a structural fracture extension length l₀ in a σ₂ direction of an ideal homogeneous reservoir and a reservoir homogeneity degree α, the specific method comprises but not limited to software simulation, physical simulation, numerical fitting and moment estimation method, a mean value of parameters is calculated based on a moment estimation method equation set of obtained data, that is, the second relevant parameter l₀ and α.

6. The method for simulating and predicting deep reservoir structural fractures in consideration of thickness change according to claim 1, wherein
in the step 9, a parameter inspection analysis and a method accuracy verification of the method are carried out to obtain a credibility result, which provides reference analysis steps and standards for exploration and development personnel using this method, and also prompts abnormal areas.
